(19) United States
(12) Patent Application Publication
(10) Pub. No.: US 2017/0201225 A1
(43) Pub. Date: Jul. 13, 2017

(54) ALL-PASS WIDEBAND PHASE SHIFTER AND OPERATING METHOD THEREOF

(71) Applicant: NATIONAL CHUNG SHAN INSTITUTE OF SCIENCE AND TECHNOLOGY, TAOYUAN CITY (TW)

(72) Inventors: YEONG-HER WANG, TAINAN CITY (TW); CHUN-CHI SU, TAINAN CITY (TW); EN-YANG LIN, TOUFEN TOWNSHIP (TW); MING-WHAY LAI, TAOYUAN CITY (TW)

(21) Appl. No.: 14/992,315

(22) Filed: Jan. 11, 2016

(51) Int. Cl. H03H 7/20; H03H 7/19

(52) U.S. Cl. CPC H03H 7/20; H03H 7/19

(57) ABSTRACT

An all-pass wideband phase shifter is introduced. Series connections in parallel between two 3 dB hybrid couplers include combining two 90-degree phase shifters and two attenuators to form a novel phase shifter framework. Under specific controls of continuous 90-degree phase shifters and attenuators in four quadrants, 360-degree all-pass phase shifting is effected by phase shifting and vector composition.

### FIELD OF THE INVENTION

The present invention relates to electronic adjustable phase shifters and more particularly to an all-pass wideband phase shifter.

### BACKGROUND OF THE INVENTION

Electronic adjustable phase shifters are widely used in phase control array antennas, radars, and phase modulation communication systems. FIG. 1 shows a conventional switch microstrip line length phase shifter 100 inside which phase shifters are connected in series, namely a 22.5-degree phase shifter 110, a 180-degree phase shifter 120, a 90-degree phase shifter 130 and a 45-degree phase shifter 140, which are arranged in sequence, started with the input end and ended at the output end. Each phase shifter has a reference line and a delay line which are connected in parallel. Specifically speaking, the 22.5-degree phase shifter 110 has a first reference line 111 and a first delay line 112 which are connected in parallel. The 180-degree phase shifter 120 has a second reference line 121 and a second delay line 122 which are connected in parallel. The 90-degree phase shifter 130 has a third reference line 131 and a third delay line 132 which are connected in parallel. The 45-degree phase shifter 140 has a fourth reference line 141 and a fourth delay line 142 which are connected in parallel. Their adjustable phases are achieved by switch microstrip line length. FIG. 2 shows a conventional high-pass/low-pass phase shifter 200 which comprises switch high-pass and low-pass filters, advantageously characterized in that its Ka frequency band has relative small circuit dimensions as well as simple circuit and layout. FIG. 3 shows a conventional transistor switch high-pass/low-pass phase shifter 300 whose design is simplified by the equivalent capacitance effect which occurs as a result when the transistor is turned on and turned off.

In addition to the aforesaid existing designs, to further bring the phase shifter wideband performance into full play, a reflective load phase shifter 400 shown in FIG. 4 and a phase shifter 500 synthesized by IQ phase and shown in FIG. 5 are introduced. The reflective load phase shifter 400 comprises a 3 dB hybrid coupler 410 with its two non-input/output points connected to reflective terminating circuits 420, 430, respectively.

Nonetheless, the switch microstrip line length phase shifter 100 shown in FIG. 1 and operated by conventional switch microstrip line length as well as the high-pass/low-pass phase shifter 200 and switch high-pass and low-pass filters phase shifter 300 shown in FIGS. 2, 3 are subjected to limits on an operating bandwidth. On the other hand, those phase shifters whose design is simplified by the equivalent capacitance effect which occurs as a result when the transistor is turned on and turned off require a precise transistor model and wiring design. The reflective load phase shifter 400 shown in FIG. 4 must be provided in the plural and connected in series in order to function as a 360-degree all-pass phase shifter, but ends up with an overly large or long circuit layout. Referring to FIG. 5, the phase shifter 500 synthesized by IQ phase is controlled with just two power sources under an operating voltage that is very sensitive to any phase change, and thus the phase shifter 500 is difficult to control. Moreover, despite the existing 180-degree large-range phase shifter framework, almost every phase shifter faces a challenge, that is, maintaining the same power output and achieving an accurate relative phase shift range within a wideband.

### SUMMARY OF THE INVENTION

Every conventional phase shifter is subjected to limits on available bandwidth. The objective of the present invention is to not only provide an all-pass wideband phase shifter but also attain the advantages of operating an 360-degree all-pass phase shifter by techniques related to phase shift and vector synthesis, with a view to effectuating performance enhancement in terms of the application of mobile communication technology.

The objective and technical solution of the present invention are achieved as described below. The present invention provides an all-pass wideband phase shifter which comprises a first 3 dB hybrid coupler, a second 3 dB hybrid coupler, a first attenuator, a second attenuator, a first continuous phase shifter and a second continuous phase shifter. The first 3 dB hybrid coupler has a signal input end, a first grounding resistor, a first series-connection starting end and a second series-connection starting end to allow a first distribution signal to be sent from the first series-connection starting end at the first series-connection path and allow a second distribution signal to be sent from the second series-connection starting end at the second series-connection path. The second 3 dB hybrid coupler has a signal output end, a second grounding resistor, a first series-connection terminating end and a second series-connection terminating end, so as to vector synthesize the first distribution signal and the second distribution signal. The first attenuator is disposed in the first series-connection path which connects the first series-connection starting end and the first series-connection terminating end, so as to attenuate and intercept the first distribution signal. The second attenuator is disposed in the second series-connection path which connects the second series-connection starting end and the second series-connection terminating end, so as to attenuate and intercept the second distribution signal. The first continuous phase shifter is disposed in the first series-connection path which connects the first series-connection starting end and the first series-connection terminating end, so as to continuously and discontinuously adjust the phases of the first distribution signal. The second continuous phase shifter is disposed in the second series-connection path which connects the second series-connection starting end and the second series-connection terminating end, so as to continuously and discontinuously adjust the phases of the second distribution signal. An all-pass phase shift is formed by IQ phase synthesis and continuous phase shift according to the four quadrant model.

The objective and technical solution of the present invention are achieved as described below.

In the aforesaid all-pass wideband phase shifter, the first continuous phase shifter and the second continuous phase shifter each have a 0˜90 degrees of continuously adjustable angle.

In the aforesaid all-pass wideband phase shifter, especially in first quadrant-based continuous phase shift mode, the first attenuator intercepts the first distribution signal, whereas the second continuous phase shifter adjusts 0˜90 degrees of phase of the second distribution signal; in the third quadrant-based continuous phase shift mode, the second attenuator intercepts the second distribution signal, whereas the first continuous phase shifter adjusts 0˜90 degrees of phases of the first distribution signal, wherein, in the second quadrant-based continuous phase shift mode, the first continuous phase shifter fixes the phase of the first distribution signal to the 90 degree so as for the first distribution signal to be attenuated and adjusted with the first attenuator, whereas the second continuous phase shifter fixes the phase of the second distribution signal to the 0 degree so as for the second distribution signal to be attenuated and adjusted with the second attenuator, thereby being vector synthesized in the second 3 dB hybrid coupler, wherein, in the fourth quadrant-based continuous phase shift mode, the first continuous phase shifter fixes the phase of the first distribution signal to the 0 degree so as for the first distribution signal to be attenuated and adjusted with the first attenuator, whereas the second continuous phase shifter fixes the phase of the second distribution signal to the 90 degree so as for the second distribution signal to be attenuated and adjusted with the second attenuator, thereby being vector synthesized in the second 3 dB hybrid coupler.

Given the above technical solution, the present invention effectuates a wideband phase shifter. The all-pass wideband phase shifter of the present invention attains 0/180-degree wideband phase shift with two 3 dB hybrid couplers, effectuates between two couplers series connections in parallel which include combining two 90-degree phase shifters and two attenuators, and enables a 360-degree all-pass phase shifter to operate under the control of continuous 90-degree phase shifters and attenuators. Hence, the resultant novel phase shifter framework is capable of IQ phase synthesis and functioning as a 0˜90-degree continuous phase shifter to thereby effectuate the operation of the all-pass wideband phase shifter.

### BRIEF DESCRIPTION OF THE DRAWINGS

FIG. 1 is a schematic view of the wiring framework of a conventional switch microstrip line length phase shifter;

FIG. 2 is a schematic view of the wiring framework of a conventional switch high-pass/low-pass phase shifter;

FIG. 3 is a schematic view of the wiring framework of a conventional transistor switch high-pass/low-pass phase shifter;

FIG. 4 is a schematic view of the wiring framework of a conventional reflective load phase shifter;

FIG. 5 is a schematic view of the wiring framework of a phase shifter of a conventional IQ phase synthesis;

FIG. 6 is a schematic view of the framework of an all-pass wideband phase shifter according to a preferred embodiment of the present invention;

FIG. 7 is a schematic view of a phase operation mode of the all-pass wideband phase shifter in the four quadrants according to a preferred embodiment of the present invention;

FIG. 8 is a graph of insertion loss against operating frequency of the all-pass wideband phase shifter according to a preferred embodiment of the present invention; and

FIG. 9 is a graph of phase change against operating frequency of the all-pass wideband phase shifter according to a preferred embodiment of the present invention.

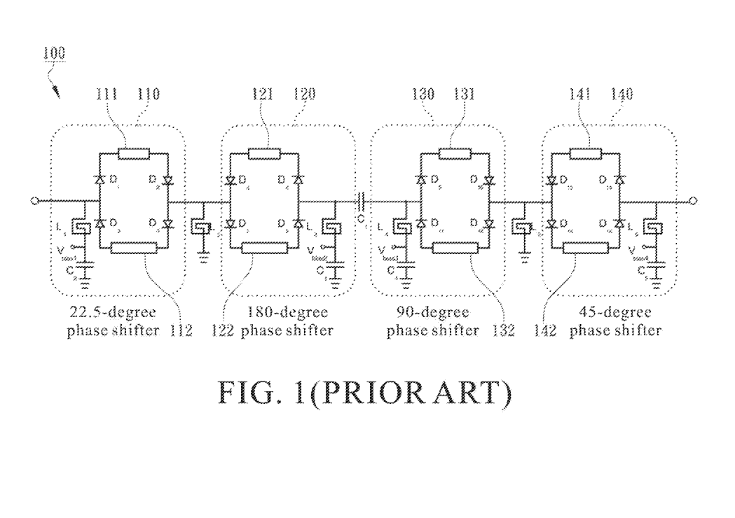

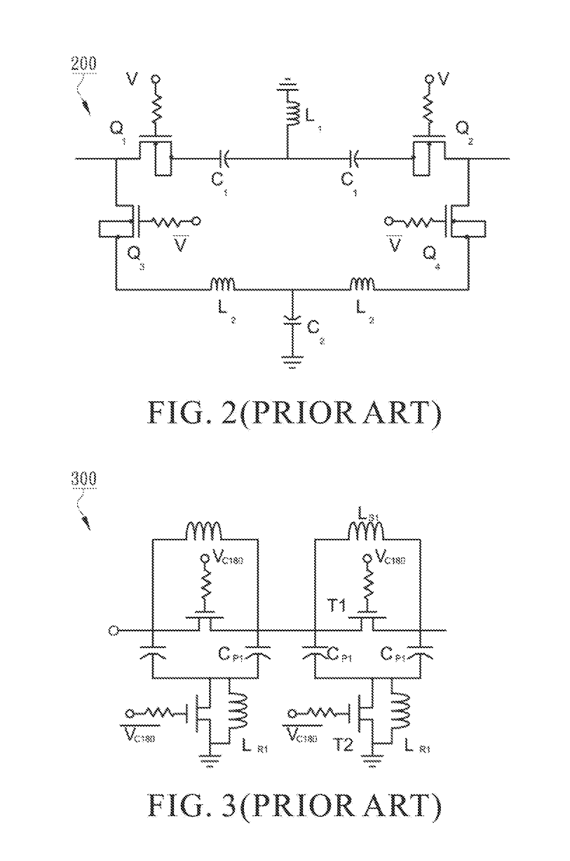

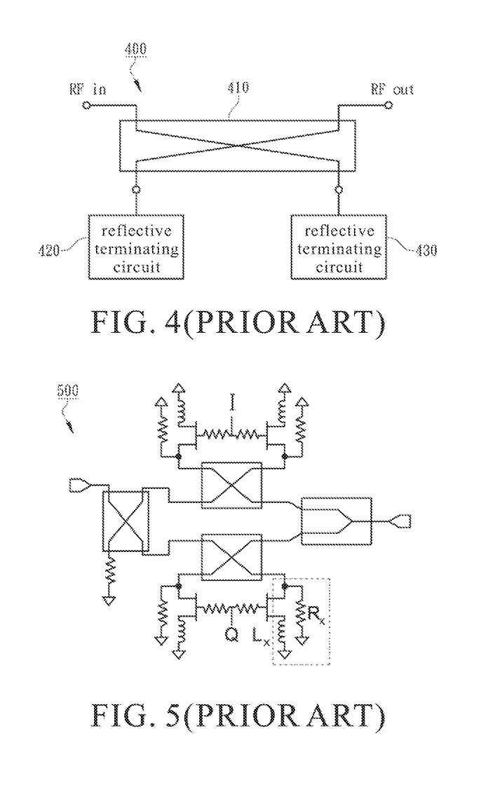

### DETAILED DESCRIPTION OF THE PREFERRED EMBODIMENTS

The embodiments of the present invention are hereunder described with reference to the accompany drawing. Although the accompanying drawings are schematic diagrams illustrative of the framework and implementation of the present invention and thus only components and combinations thereof related to the present invention are shown, the diagrams are not drawn to scale in terms of the quantity, shape and dimensions of the components; instead, the dimensions of the components shown in the diagram may be exaggerated and diminished as needed for illustrative sake. Hence, the actual quantity, shape and dimensions of the components shown in the diagrams are attributed to design choices, and related layouts of component can be more complicated than they are shown in the diagrams.

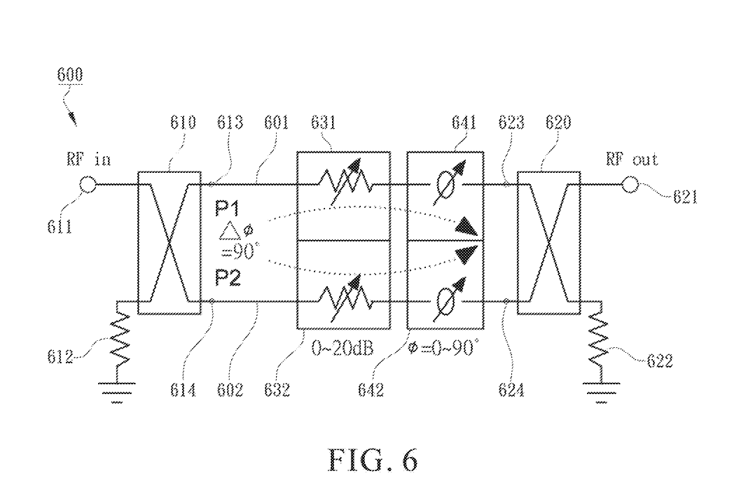

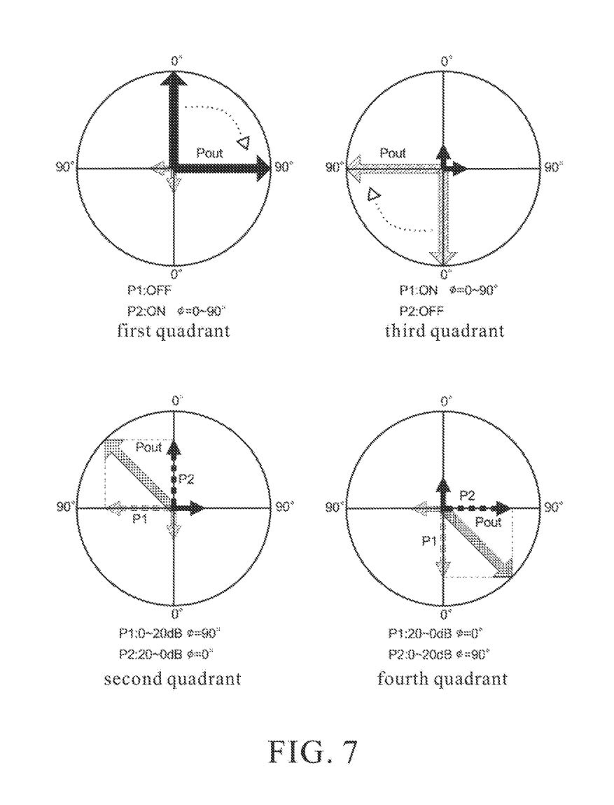

According to a preferred embodiment of the present invention, an all-pass wideband phase shifter 600 is illustrated with FIG. 6 and FIG. 7. FIG. 6 is a schematic view of the framework of an all-pass wideband phase shifter according to a preferred embodiment of the present invention. FIG. 7 is a schematic view of a phase operation mode of the all-pass wideband phase shifter in the four quadrants according to a preferred embodiment of the present invention. As shown in the diagrams, the all-pass wideband phase shifter 600 comprises a first 3 dB hybrid coupler 610, a second 3 dB hybrid coupler 620, a first attenuator 631, a second attenuator 632, a first continuous phase shifter 641 and a second continuous phase shifter 642.

The first 3 dB hybrid coupler 610 has a signal input end 611, a first grounding resistor 612, a first series-connection starting end 613 and a second series-connection starting end 614. A first distribution signal P1 is sent from the first series-connection starting end 613 which a first series-connection path 601 starts with. A second distribution signal P2 is sent from the second series-connection starting end 614 which a second series-connection path 602 ends at. The second 3 dB hybrid coupler 620 has a signal output end 621, a second grounding resistor 622, a first series-connection terminating end 623 and a second series-connection terminating end 624 so as to vector synthesize the first distribution signal P1 and the second distribution signal P2. An output signal Pₒᵤₜ sent from the second 3 dB hybrid coupler 620 through the signal output end 621 is commensurate with the phase change of the first distribution signal P1 in different quadrants, the phase change of the second distribution signal P2, and is vector synthesized after being attenuated at a fixed phase of the first distribution signal P1 and the second distribution signal P2 as shown in FIG. 7.

The first attenuator 631 is disposed in the first series-connection path 601 which connects the first series-connection starting end 613 and the first series-connection terminating end 623, so as to attenuate and intercept the first distribution signal P1. The second attenuator 632 is disposed in the second series-connection path 602 which connects the second series-connection starting end 614 and the second series-connection terminating end 624, so as to attenuate and intercept the second distribution signal P2.

The first continuous phase shifter 641 is disposed in the first series-connection path 601 which connects the first series-connection starting end 613 and the first series-connection terminating end 623 so as to continuously and discontinuously adjust the phase of the first distribution signal P1. The second continuous phase shifter 642 is connected in the second series-connection path 602 which connects the second series-connection starting end 614 and the second series-connection terminating end 624 so as to continuously and discontinuously adjust the phase of the second distribution signal P2. The first continuous phase shifter 641 and the second continuous phase shifter 642 each have a 0˜90 degree of continuously adjustable angle, i.e., phase angle φ, which can be changed and adjusted within the 0˜90° range as shown in FIG. 6.

An all-pass phase shift is formed by IQ phase synthesis and continuous phase shift according to the four quadrant model.

Referring to FIG. 7, in the first quadrant-based continuous phase shift mode, the first attenuator 631 intercepts the first distribution signal P1, whereas the second continuous phase shifter 642 adjusts the 0˜90 degrees of phase of the second distribution signal P2; hence, the phase angle φ of the second distribution signal P2 equals 0˜90 degrees and is commensurate with the output signal Pₒᵤₜ. In the third quadrant-based continuous phase shift mode, the second attenuator 632 intercepts the second distribution signal P2, whereas the first continuous phase shifter 641 adjusts the 0˜90 degrees of phase of the first distribution signal P1; hence, phase angle φ of the first distribution signal P1 equals 0˜90 degrees and is commensurate with output signal Pₒᵤₜ. In the second quadrant-based continuous phase shift mode, the first continuous phase shifter 641 fixes the phase of the first distribution signal P1 to the 90 degree so as for the first distribution signal P1 to be attenuated and adjusted with the first attenuator 631, whereas the second continuous phase shifter 642 fixes the phase of the second distribution signal P2 to the 0 degree so as for the second distribution signal P2 to be attenuated and adjusted with the second attenuator 632, thereby being vector synthesized in the second 3 dB hybrid coupler 620. Therefore, the phase angle of the first distribution signal P1 is fixed to the 90 degree, whereas the phase angle of the second distribution signal P2 is fixed to the 0 degree, wherein the first distribution signal P1 and the second distribution signal P2 are attenuated to thereby generate the output signal Pₒᵤₜ by vector synthesis. In the fourth quadrant-based continuous phase shift mode, the first continuous phase shifter 641 fixes the phase of the first distribution signal P1 to the 0 degree so as for the first distribution signal P1 to be attenuated and adjusted with the first attenuator 631, whereas the second continuous phase shifter 642 fixes the phase of the second distribution signal P2 to the 90 degree so as for the second distribution signal P2 to be attenuated and adjusted with the second attenuator 632, thereby being vector synthesized in the second 3 dB hybrid coupler 620. The phase angle of the first distribution signal P1 is fixed to the 0 degree, whereas the phase angle of the second distribution signal P2 is fixed to the 90 degree, wherein the first distribution signal P1 and the second distribution signal P2 are attenuated to thereby generate the output signal Pₒᵤₜ by vector synthesis.

Referring to FIG. 6, the all-pass wideband phase shifter 600 is capable of IQ phase synthesis and functioning as a 0˜90-degree continuous phase shifter. The second attenuator 632 intercepts the second distribution signal P2, whereas the first distribution signal P1 undergoes continuous 0˜90 degrees of phase change (φ=0˜90°. Referring to FIG. 7, in the third quadrant operation mode, the first attenuator 631 intercepts the first distribution signal P1, whereas the second distribution signal P2 undergoes continuous 0˜90 degrees of phase change (φ=0˜90° in the same way as the first quadrant operation mode shown in FIG. 7. The first distribution signal P1 operates at the 90 degree, whereas the second distribution signal P2 operates at the 0 degree, so as to control the attenuation of the first distribution signal P1 and second distribution signal P2, respectively, and then undergoes vector synthesis, such that the output signal Pₒᵤₜ undergoes 0˜90 degrees of continuous phase shift in the second quadrant shown in FIG. 7. Likewise, the first distribution signal P1 operates at the 0 degree, whereas the second distribution signal P2 operates at the 90 degree, so as to control the attenuation of the first distribution signal P1 and second distribution signal P2, respectively, and then undergoes vector synthesis, such that the output signal Pₒᵤₜ undergoes 0˜90 degrees of continuous phase shift in the fourth quadrant shown in FIG. 7.

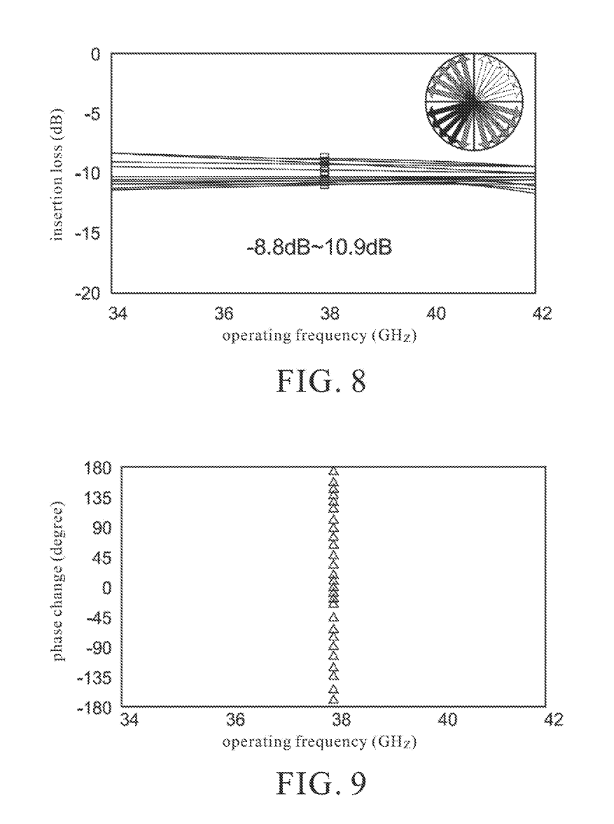

Referring to FIG. 8, given the phase shifter framework of the present invention, a chip capable of IQ phase synthesis and functioning as a 0˜90-degree continuous phase shifter is provided to simulate a 360-degree 5 bit operation mode such that the resultant insertion loss amounts to −8.8˜−10.9 dB or so at 38 GHz. Referring to FIG. 9, the largest phase error equals 5˜6 degrees whenever the operating frequency operates within a range of 4 GHz in the 38 GHz bandwidth.

The present invention provides an all-pass wideband phase shifter which is capable of phase shift and vector synthesis to thereby function as a 360-degree all-pass phase shifter, thereby effectuating performance enhancement in terms of the application of mobile communication technology.

The present invention is disclosed above by preferred embodiments. However, the preferred embodiments should not be interpreted as restrictive of the scope of the present invention. Hence, all equivalent changes made to the claims of the present invention should fall within the scope of the present invention.

What is claimed is:

1. An all-pass wideband phase shifter, comprising:
a first 3 dB hybrid coupler having a signal input end, a first grounding resistor, a first series-connection starting end and a second series-connection starting end to allow a first distribution signal to be sent from the first series-connection starting end at the first series-connection path and allow a second distribution signal to be sent from the second series-connection starting end at the second series-connection path;
a second 3 dB hybrid coupler having a signal output end, a second grounding resistor, a first series-connection terminating end and a second series-connection terminating end, so as to vector synthesize the first distribution signal and the second distribution signal;
a first attenuator disposed in the first series-connection path connecting the first series-connection starting end and the first series-connection terminating end, so as to attenuate and intercept the first distribution signal;
a second attenuator disposed in the second series-connection path connecting the second series-connection starting end and the second series-connection terminating end, so as to attenuate and intercept the second distribution signal;
a first continuous phase shifter disposed in the first series-connection path connecting the first series-connection starting end and the first series-connection terminating end, so as to continuously and discontinuously adjust a phase of the first distribution signal; and
a second continuous phase shifter disposed in the second series-connection path connecting the second series-connection starting end and the second series-connection terminating end, so as to continuously and discontinuously adjust a phase of the second distribution signal,
wherein an all-pass phase shift is formed by IQ phase synthesis and continuous phase shift according to the four quadrant model.

2. The all-pass wideband phase shifter of claim 1, wherein the first continuous phase shifter and the second continuous phase shifter have 0˜90 degrees of continuously adjustable angles.

3. The all-pass wideband phase shifter of claim 2, wherein, in the first quadrant-based continuous phase shift mode, the first attenuator intercepts the first distribution signal, whereas the second continuous phase shifter adjusts 0˜90 degrees of phases of the second distribution signal, wherein, in the third quadrant-based continuous phase shift mode, the second attenuator intercepts the second distribution signal, whereas the first continuous phase shifter adjusts 0˜90 degrees of phases of the first distribution signal, wherein, in the second quadrant-based continuous phase shift mode, the first continuous phase shifter fixes the phase of the first distribution signal to the 90 degree so as for the first distribution signal to be attenuated and adjusted with the first attenuator, whereas the second continuous phase shifter fixes the phase of the second distribution signal to the 0 degree so as for the second distribution signal to be attenuated and adjusted with the second attenuator, thereby being vector synthesized in the second 3 dB hybrid coupler, wherein, in the fourth quadrant-based continuous phase shift mode, the first continuous phase shifter fixes the phase of the first distribution signal to the 0 degree so as for the first distribution signal to be attenuated and adjusted with the first attenuator, whereas the second continuous phase shifter fixes the phase of the second distribution signal to the 90 degree so as for the second distribution signal to be attenuated and adjusted with the second attenuator, thereby being vector synthesized in the second 3 dB hybrid coupler.

4. A method of operating an all-pass wideband phase shifter, the method comprising the step of providing an all-pass wideband phase shifter comprising:
a first 3 dB hybrid coupler having a signal input end, a first grounding resistor, a first series-connection starting end and a second series-connection starting end and adapted to output a first distribution signal from the first series-connection starting end in a first series-connection path and output a second distribution signal from the second series-connection starting end in a second series-connection path;
a second 3 dB hybrid coupler having a signal output end, a second grounding resistor, a first series-connection terminating end and a second series-connection terminating end and adapted to vector synthesize the first distribution signal and the second distribution signal;
a first attenuator disposed in the first series-connection path connecting the first series-connection starting end and the first series-connection terminating end, so as to attenuate and intercept the first distribution signal;
a second attenuator disposed in the second series-connection path connecting the second series-connection starting end and the second series-connection terminating end, so as to attenuate and intercept the second distribution signal;
a first continuous phase shifter disposed in the first series-connection path connecting the first series-connection starting end and the first series-connection terminating end, so as to continuously and discontinuously adjust a phase of the first distribution signal; and
a second continuous phase shifter disposed in the second series-connection path connecting the second series-connection starting end and the second series-connection terminating end, so as to continuously and discontinuously adjust a phase of the second distribution signal,
wherein a phase shift process is performed to form an all-pass phase shift by IQ phase synthesis and continuous phase shift according to the four quadrant model.

5. The method of claim 4, wherein the first continuous phase shifter and the second continuous phase shifter has 0˜90 degrees of continuously adjustable angles, and the phase shift process comprises:
effecting a first quadrant-based continuous phase shift mode to allow the first attenuator to intercept the first distribution signal and allow the second continuous phase shifter to adjust 0˜90 degrees of phase of the second distribution signal;
effecting a third quadrant-based continuous phase shift mode to allow the second attenuator to intercept the second distribution signal and allow the first continuous phase shifter to adjust 0˜90 degrees of phase of the first distribution signal;
effecting a second quadrant-based continuous phase shift mode to allow the first continuous phase shifter to fix the phase of the first distribution signal to the 90 degree so as for the first distribution signal to be attenuated and adjusted with the first attenuator, and allow the second continuous phase shifter to fix the phase of the second distribution signal to the 0 degree so as for the second distribution signal to be attenuated and adjusted with the second attenuator, thereby being vector synthesized in the second 3 dB hybrid coupler; and
effecting a fourth quadrant-based continuous phase shift mode to allow the first continuous phase shifter to fix the phase of the first distribution signal to the 0 degree so as for the first distribution signal to be attenuated and adjusted with the first attenuator, and allow the second continuous phase shifter to fix the phase of the second distribution signal to the 90 degree so as for the second distribution signal to be attenuated and adjusted with the second attenuator, thereby being vector synthesized in the second 3 dB hybrid coupler.
